(19) United States
(12) Patent Application Publication
(10) Pub. No.: US 2025/0372292 A1
(43) Pub. Date: Dec. 4, 2025

(54) METHOD FOR REDUCING MAGNETISM ON A MOLD CHASE

(71) Applicant: TEXAS INSTRUMENTS INCORPORATED, DALLAS, TX (US)

(72) Inventors: Cesar BUCASAS, TARLAC (PH); Richard SUMALINOG, MABALACAT CITY (PH); Piel Angelo ORIAS, ANGELES (PH)

(21) Appl. No.: 18/675,719

(22) Filed: May 28, 2024

(51) Int. Cl. H01F 13/00; H01L 21/56; H01L 21/67; H01L 23/00; H01L 23/29; H01L 23/31

(52) U.S. Cl. CPC H01F 13/006; H01L 21/565; H01L 21/67126; H01L 23/29; H01L 23/3121; H01L 24/48; H01L 2224/48225; H01L 2924/1815

(57) ABSTRACT

A system and method of demagnetizing a mold machine for forming a magnetic mold compound of electronic devices is provided. The method includes performing a molding process with a mold machine to form a magnetic mold compound on electronic devices and detecting magnetic fields in a mold chase of the mold machine via a gaussmeter. The molding process of the mold machine is ceased responsive to determining that a strength of at least one detected magnetic field exceeds a threshold and the mold chase is demagnetized via a demagnetizer.

### TECHNICAL FIELD

The present disclosure relates to a process for molding a magnetic mold compound, and more specifically to reducing magnetism on a mold chase during the magnetic mold process for integrated circuit packages.

### BACKGROUND

During a molding process for molding a magnetic mold compound on integrated circuit (IC) devices to form IC packages, the magnetic mold compound has metal fillers that can become magnetized if exposed to a magnetic field. The magnetic mold compound is dispensed in a mold chase in powder form. During the molding process, the mold chase is heated such that the magnetic mold compound becomes liquid prior to forming the mold over the IC devices. During the molding process, however, portions of the mold chase can become magnetized since the mold chase is made from a metal (e.g., chrome). The magnetization of the mold chase causes magnetic field(s), which in turn attracts the metal fillers to the magnetic field(s). Thus, concentrated regions of metal fillers are formed in the magnetic mold compound. The concentrated regions of metal fillers caused by the magnetic field(s) in the magnetic mold compound result in an irregular distribution of metal throughout the magnetic mold compound.

### SUMMARY

In a described example, a method includes performing a molding process with a mold machine to form a magnetic mold compound on electronic devices and detecting magnetic fields in a mold chase of the mold machine via a gaussmeter. The molding process of the mold machine is ceased responsive to determining that a strength of at least one detected magnetic field exceeds a threshold and the mold chase is demagnetized via a demagnetizer.

In another described example, a method includes demagnetizing a mold chase during molding a mold compound on electronic devices that includes activating a gaussmeter coupled to a mold chase in the mold machine to detect magnetic fields and demagnetizing the mold chase via a demagnetizer responsive to detecting that a strength of at least one detected magnetic field exceeds a threshold. A magnetic mold compound is dispensed in a powder state into a cavity of a lower mold chase and the lower mold chase is heated to a temperature to transform the magnetic mold compound from the powder state to a liquid state. The lower mold chase is clamped to an upper mold chase for a time period to form the magnetic mold compound on the electronic devices attached to the upper mold chase. The lower mold chase is unclamped from the upper mold chase, and the electronic devices are removed from the upper mold chase.

In still another described example, a mold system includes a mold machine configured to form a mold compound on electronic devices, where the mold machine includes a controller and a mold chase. A gaussmeter is coupled to the mold machine and is configured to detect magnetic fields of the mold chase. A controller is configured to provide a control signal responsive to determining a strength of at least one of the detected magnetic fields exceeds a magnetization threshold. A demagnetizer is configured to demagnetize the mold chase responsive to the control signal.

In still another described example, an electronic device includes a leadframe having a die pad and leads. A die having an active side is disposed on the die pad and a mold compound encapsulates the die. Metal fillers in the mold compound are randomly dispersed.

### BRIEF DESCRIPTION OF THE DRAWINGS

FIG. 1 is a block diagram illustration of a mold system that includes a mold machine.

FIGS. 2A and 2B are alternative examples of the mold system illustrated in FIG. 1.

FIGS. 3A and 3B are side view illustrations of a lower mold chase that illustrate the effects of the lower mold chase being exposed to a magnetic field.

FIG. 4 is a block diagram flow chart describing a molding process.

FIG. 5 is a block diagram flow chart describing demagnetization processes.

FIGS. 6A and 6B are cross-sectional views of an example electronic device molded in a magnetic mold compound.

### DETAILED DESCRIPTION

During a molding process for molding a magnetic mold compound on integrated circuit (IC) devices to form IC packages, the magnetic mold compound has metal fillers that can become magnetized if exposed to a magnetic field. The magnetic mold compound is dispensed in a mold chase in powder form. During the molding process, the mold chase is heated such that the magnetic mold compound becomes liquid prior to forming the mold over the IC devices. During the molding process, however, portions of the mold chase can become magnetized since the mold chase is made from a metal (e.g., chrome). The magnetization of the mold chase causes magnetic field(s), which in turn attracts the metal fillers to the magnetic field(s). Thus, concentrated regions of metal fillers are formed in the magnetic mold compound. The concentrated regions of metal fillers caused by the magnetic field(s) in the magnetic mold compound result in an irregular distribution of metal in the magnetic mold compound. As a result, the concentrated regions of the metal fillers in the magnetic mold compound can compromise the functionality of the IC package as well as appearance.

Disclosed herein is a mold system and a molding process in a mold chase to reduce or prevent magnetic fields from affecting the distribution of the metal fillers in magnetic mold compound. In addition to molding electronic devices (e.g., integrated inductors) in an integrated circuit (IC) package, the molding process also includes detecting a magnetic field in a mold chase in the mold machine, measuring a magnetic field strength, determining if the magnetic field strength exceeds a threshold, and demagnetizing the mold chase if the threshold is exceeded.

Magnetic mold compound is used as a molding compound to encapsulate electronic devices (e.g., integrated inductors) in an integrated circuit (IC) package. The mold system is a closed loop system configured to detect magnetic fields in real-time and to cease operation of the mold machine upon detection of a magnetic field. For example, if a strength (intensity) of a detected magnetic field exceeds a threshold stored in a memory of a controller, the mold machine, via the controller, ceases operation of the mold machine. The mold system provides an effective means to maintain and control molding tools and process for molding the magnetic mold compound.

The method includes prohibiting contact of any type of magnetizing tools or materials with the mold chase or any other mold machine part that is in contact with magnetic mold compound. The method further includes establishing periodic mold chase preventive maintenance and implementing a demagnetizer as part of a preventive maintenance checklist. The method also includes incorporating a gaussmeter into the mold system to detect and monitor the presence of magnetic fields in the mold chase. Specifically, one or more probes from the gaussmeter are coupled to the mold chase to detect and monitor the presence of the magnetic fields. If the strength of at least one detected magnetic field exceeds a threshold, the mold machine is automatically stopped, and the mold chase is demagnetized with a demagnetizer.

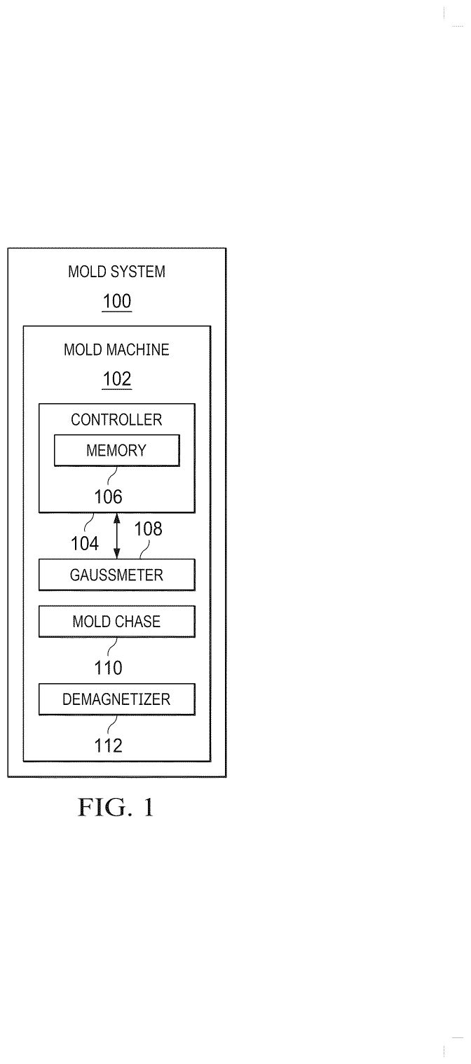

FIG. 1 is a block diagram illustration of a mold system 100 that includes a mold machine 102. The mold machine 102 includes a controller 104 having a memory 106, a gaussmeter 108, a mold chase 110, and a demagnetizer 112. The mold chase 110 is a mold in which a molding compound is dispensed into the mold and is molded under heat and pressure for the purpose of protecting IC chips or dies. During the molding process, after the molding compound is dispensed the mold chase 110, the mold chase is then preheated to a temperature and controlled to achieve a desired result. A clamping force is applied to the mold chase 110 to provide an appropriate pressure for a period of time. The controller 104 controls the operation of the mold machine 102. Specifically, inter alia, the controller 104 of the mold machine 102 controls the preheating, monitors and controls the mold temperature, calculates and controls the clamping force, and controls the time.

As will be illustrated below, the gaussmeter 108 includes one or more probes coupled to the mold chase 110. The gaussmeter 108, via the probes, detects magnetic fields and monitors a strength of the detected magnetic fields. As illustrated in FIG. 1, the gaussmeter 108 is in communication with the controller 104. Specifically, the gaussmeter 108 and the controller 104 can each receive and transmit data to and from each other. Thus, any detection of a magnetic field by the gaussmeter 108 is transmitted to the controller 104. If a strength of the detected magnetic field exceeds a threshold (magnetization threshold) stored in the memory 106, the controller 104 automatically ceases operation of the mold machine 102. As will be explained in more detail below, the mold chase 110 is demagnetized, via the demagnetizer 112, and the molding process is continued.

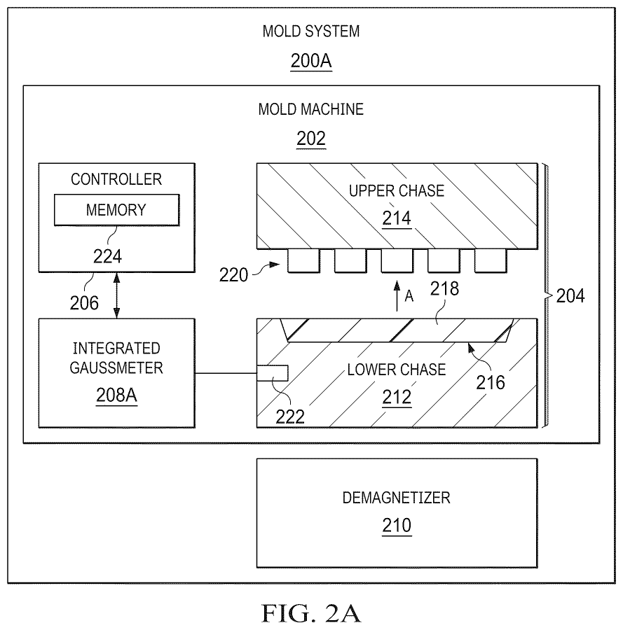

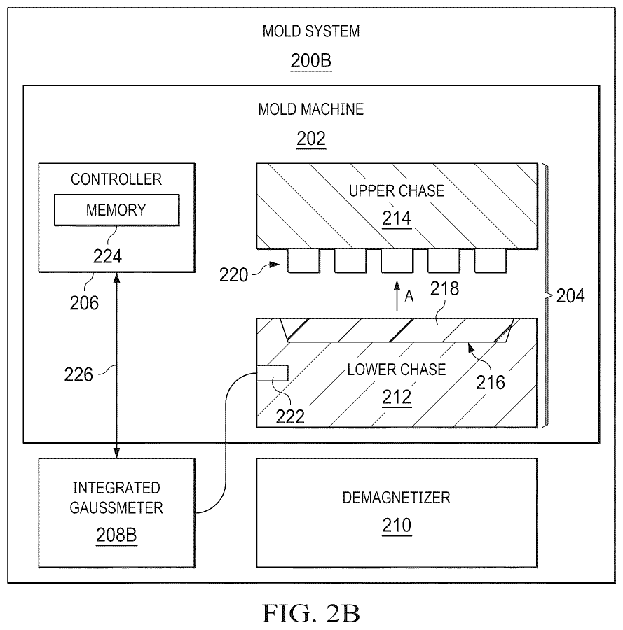

FIGS. 2A and 2B are alternative examples of the mold system 100 illustrated in FIG. 1. Specifically, FIG. 2A is an example mold system 200A that includes a gaussmeter that is integrated into a mold machine and FIG. 2B is an example mold system 200B where the gaussmeter is external to the mold machine. The mold systems 200A, 200B illustrated in FIGS. 2A and 2B respectively are similar to the example mold system illustrated in FIG. 1. Thus, reference is to be made to the example in FIG. 1 in the following description of the examples in FIGS. 2A and 2B.

Referring to FIG. 2A, the mold system 200A is comprised of a mold machine 202 that includes a mold chase 204, a controller 206, an integrated gaussmeter 208A, and a demagnetizer 210. The mold chase 204 is comprised of a lower mold chase 212 and an upper mold chase 214. A cavity 216 is defined in the lower mold chase 212 that is configured to receive and hold a mold compound (e.g., magnetic mold compound) 218. During operation of the mold machine 202, described below, the lower mold chase 212 moves in a direction toward the upper mold chase 214 as indicated by the arrow A, such that electronic devices (e.g., IC dies (chips) attached to leadframes of an IC) 220 removably attached to the upper mold chase 214 are immersed in the mold compound 218. The mold compound 218 encapsulates the die 220 to thereby provide protection to the die 220.

The integrated gaussmeter 208A is integrated into the mold machine 202 and includes one or more probes 222 coupled to the mold chase 204. The probe(s) 222 can be coupled to either the lower mold chase 212, the upper mold chase 214, or both. In addition, the probes 222 can be coupled to any portion (e.g., sides, bottom, corners, etc.) of the lower and/or upper mold chase 212, 214. The probe(s) 222 are configured to detect the presence of a magnetic field. Any detection of a magnetic field is transmitted to the controller 206. If at any time a strength (intensity) of the magnetic field exceeds a threshold (e.g., 0.5 mT or 5G) stored in a memory 224, the controller 206 will cease operation of the mold machine 202 to allow demagnetization of the mold chase 204 via the demagnetizer 210. Although, the demagnetizer 210 is illustrated as being external to the mold machine 202, in an alternative example, the demagnetizer 210 can be integrated into the mold machine 202 proximate to the mold chase 204.

The example mold system 200B in FIG. 2B is similar to the mold system 200A in FIG. 2A. Thus, like components between the mold system 200A illustrated in FIG. 2A and the mold system 200B illustrated in FIG. 2B shall be designated with the same reference number, and any description regarding the like components will not be repeated. The one exception between the mold system 200A of FIG. 2A and the mold system 200B of FIG. 2B is the location of the gaussmeter 208B. Specifically, the gaussmeter 208B is not integrated into the mold machine 202. Rather, the gaussmeter 208B is external to the mold machine 202. The external gaussmeter 208B is coupled to the controller 206 via a link 226, such that the external gaussmeter 208B and the controller 206 can each receive and transmit data to and from each other. As in the mold system 200A, the one or more probes 222 are coupled to the mold chase 204. As in the mold system of FIG. 2A, the probe(s) 222 are configured to detect the presence of a magnetic field and any detection of a magnetic field is transmitted to the controller 206. If at any time a strength or intensity of the magnetic field exceeds the threshold (e.g., 0.5 mT or 5G) stored in the memory 224, the controller 206 will cease operation of the mold machine 202 to allow demagnetization of the mold chase 204 via the demagnetizer 210.

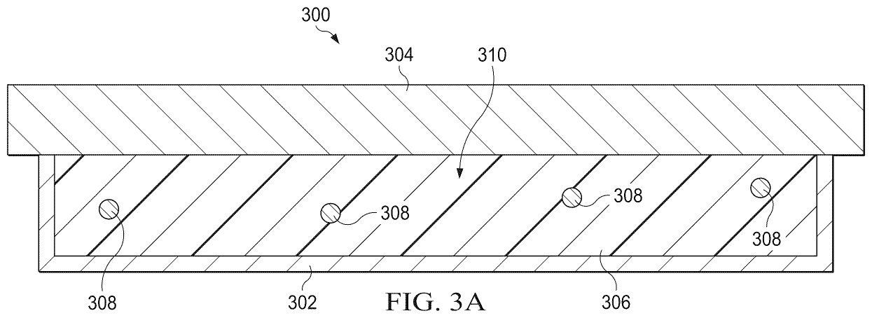

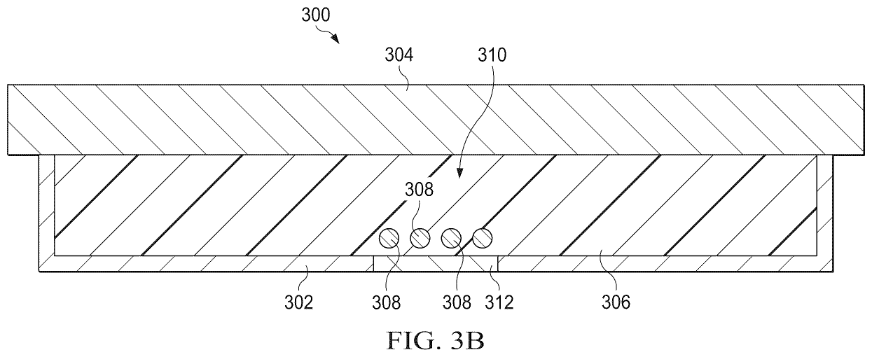

FIGS. 3A and 3B illustrate the effects of a mold chase 300 being exposed to a magnetic field thereby magnetizing that portion of the mold chase 300. The mold chase 300 illustrated in FIGS. 3A and 3B is similar to the example mold chase 110 and 204 illustrated in FIGS. 1 and 2A, 2B respectively. Thus, reference is to be made to the examples in FIGS. 1, 2A, and 2B in the following description of the example in FIGS. 3A and 3B. As in the examples described above, the mold chase 300 includes a lower mold chase 302 and an upper mold chase 304. In the examples illustrated in FIGS. 3A and 3B, the lower mold chase 302 is shown in a clamped configuration.

Referring both to FIGS. 3A and 3B, a magnetic mold compound 306 that includes metal fillers (e.g., iron chromium) 308 is dispensed in a cavity 310 of the lower mold chase 302. In FIG. 3A, the lower mold chase 302 has not been exposed to a magnetic field and is thus not magnetized. As a result, the metal fillers 308 are randomly distributed though out the magnetic mold compound 306 in a uniform manner. On the other hand, in FIG. 3B the lower mold chase 302 has been exposed to a magnetic field and thus a portion 312 of the lower mold chase 302 has become magnetized. As a result, the metal fillers 308 are attracted to the magnetized portion 312 of the lower mold chase 302 and thus become concentrated near the magnetized portion 312. Consequently, the metal fillers 308 are not randomly distributed throughout the magnetic mold compound 306 thereby compromising the molding process and the performance of the IC.

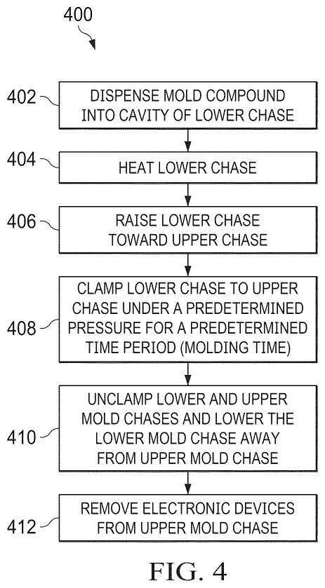

FIG. 4 is a block diagram flow chart describing a molding process 400 that includes detecting and monitoring magnetic fields in a mold chase to prevent magnetic fields from affecting the distribution of the metal fillers in the magnetic mold compound. Though depicted sequentially as a matter of convenience, at least some of the actions shown can be performed in a different order and/or performed in parallel. Alternatively, some implementations may perform only some of the actions shown. Still further, although the example illustrated in FIG. 4 is an example method illustrating a method of detecting magnetic fields in a mold chase, other methods and configurations are possible.

At 402, a mold compound (e.g., magnetic mold compound 218) is dispensed in a cavity (e.g., 216) of a lower mold chase (e.g., 212). The mold compound (e.g., 218) is in a crushed powder state at time of dispensing. At 404, the lower mold chase (e.g., 212) is heated to a temperature (e.g., 175° C.) to heat the mold compound (e.g., 218) such that the mold compound (e.g., 218) is melted and liquifies. At 406, the lower mold chase (e.g., 212) is raised toward an upper mold chase (e.g., 214) such that electronic devices (e.g. 220) are immersed in the mold compound (e.g., 218). At 408, the lower and upper mold chases (e.g., 212, 214) are clamped together under a pressure (e.g., approximately 20 tons) for a period of time (molding time) (e.g., approximately 120 seconds). During the molding time the mold compound (e.g., 218) undergoes a curing process. Specifically, during the curing process, the mold compound (e.g., 218) undergoes a gelation process where the mold compound (e.g., 218) begins to solidify. At 410, after expiration of the time period (molding time), upon which a minimum hardness of the mold compound (e.g., 218) is achieved, the mold chase (e.g., 204) is unclamped and the lower mold chase (e.g., 212) is lowered away from the upper mold chase (e.g., 214). At 412, the electronic devices (e.g., 220) are removed from the upper mold chase (e.g., 214).

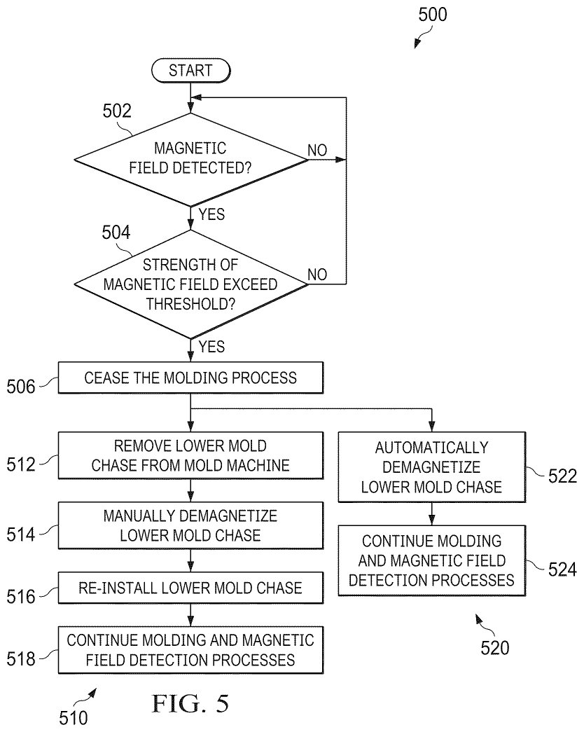

FIG. 5 is a block diagram flow chart describing detecting and measuring magnetic field strength 500 via a gaussmeter (208A, 208B). At 502, a decision is made to determine if a magnetic field has been detected. If the decision is NO, then the process returns to 502 and a decision is again made to determine if a magnetic filed field has been detected. This loop continues until a magnetic field is detected. If the decision at 502 is YES, then at 504 a decision is made to determine if a strength of the magnetic field exceeds a threshold (e.g., magnetism threshold). Specifically, the magnetic field strength, measured in ampere per meter (A/m) by the gaussmeter (e.g., 208A, 208B), is compared to a threshold stored in a memory (e.g., 224) of a controller (e.g., 206). If the decision is NO, then the process returns to 502 and the process continues. If the decision at 504 is YES, then at 506 operation of the mold machine (e.g., 202) ceases. This can be performed manually as the controller (e.g., 206) can provide an alert (e.g., audio, visual, etc.) to an operator that the threshold has been exceeded. Alternatively, the controller (e.g., 206) can automatically cease operation of the mold machine (e.g., 202) by providing a control signal to cease the molding process.

In the example where the demagnetizer (e.g., 210) is external to the mold machine (e.g., 202), a manual demagnetization sub-process 510 is performed. Specifically, at 512, the lower mold chase (e.g., 212) is removed from the mold machine (e.g., 202). At 514, the lower mold chase (e.g., 212) is manually demagnetized via the demagnetizer (e.g., 210). At 516, after manual demagnetization is completed, the lower mold chase (e.g., 212) is re-installed into the mold machine (e.g., 202). Finally, at 518 the molding process 400 and the method 500 of detecting the magnetic field continues.

In the example where the demagnetizer (e.g., 210) is integrated into the mold machine (e.g., 202), an automatic demagnetization sub-process 520 is performed. Specifically, at 522 the lower mold chase (e.g., 212) is automatically demagnetized via the integrated demagnetizer (e.g., 210). More specifically, the integrated demagnetizer (e.g., 210) is located proximate to the lower mold chase (e.g., 212) in the mold machine (e.g., 202). The demagnetizer (e.g., 210) is conveyed along the lower mold chase (e.g., 212) via a mechanism to demagnetize the lower mold chase (e.g., 212). At 524, after the automatic demagnetization process 540 is completed, the molding process 400 continues and the method 500 of detecting the magnetic field continues.

In addition to the processes explained above, other processes may be implemented to prevent magnetic fields from affecting the distribution of the metal fillers in magnetic mold compound. For example, prior to the molding process, any contact of a magnetized tool or material should be prohibited from coming in contact with the mold chase or magnetic mold compound. Establish periodic preventive maintenance on the mold chase and demagnetize lower mold chase as part of the preventive maintenance checklist. Establish proactive measures to periodically (e.g., weekly, monthly, quarterly, etc.) demagnetize mold chase and surrounding frame.

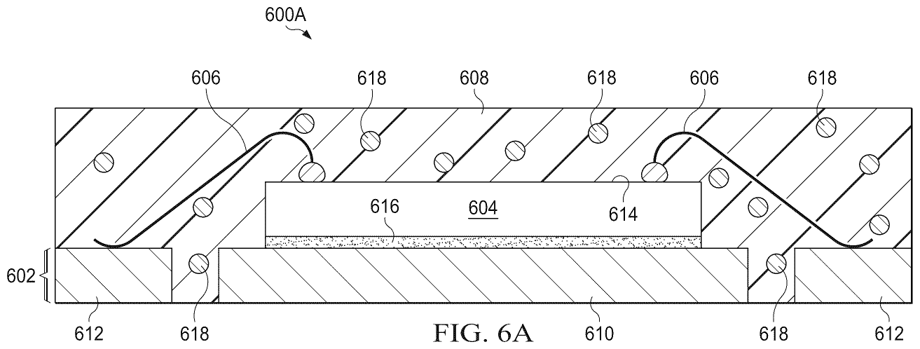

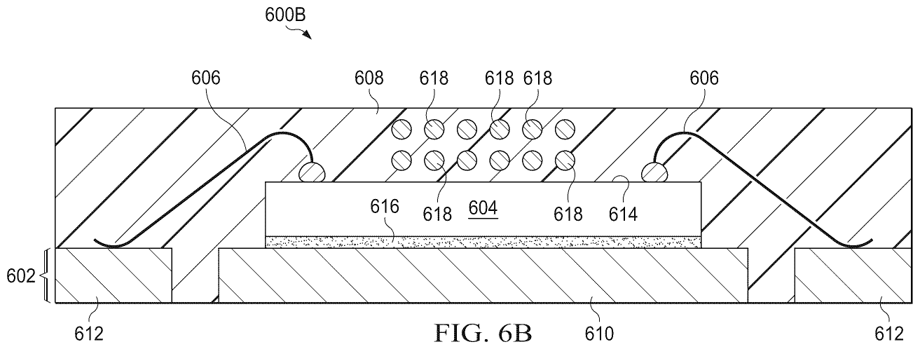

FIGS. 6A and 6B are cross-sectional views of an example electronic device (e.g., integrated circuit (IC)) 600A, 600B molded in a magnetic mold compound. In FIG. 6A the mold chase was not magnetized during the molding process, whereas in FIG. 6B the mold chase was magnetized during the molding process. The electronic device 600A, 600B includes a leadframe 602, a die 604, wire bonds 606, and a mold compound 608. The example electronic device 600A, 600B illustrated in FIGS. 6A and 6B is QFN package. The electronic device 600A, 600B, however, can be comprised of an IC package including but not limited to a Quad Flat No-Lead (QFN) Package, a Quad Flat Package (QFP), Dual In-Line Package (DIP), a Single In-Line Package (SIP), Small Outline Package (SOP), etc. In addition, the electronic device 600A, 600B can be a through-hole mount or a surface mount package. Therefore, the electronic device 600A, 600B illustrated in FIGS. 6A and 6B is for illustrative purposes only and is not intended to limit the scope of the invention.

The leadframe 602 includes a die pad 610 and leads 612. The die 604 includes an active side 614 and is disposed on the die pad 610 via a die attach material 616. The wire bonds 606 are attached to the active side 614 of the die 604 and to the leads 612. The mold compound 608 (e.g., magnetic mold compound) encapsulates the die 604 and the wire bonds 606. In some examples, the mold compound 608 covers all but one surface of the leadframe 602, where the one surface not covered faces away from the die 604.

In one example, the mold compound 608 can be comprised of a magnetic mold compound that includes metal fillers (e.g., iron chromium) 618. As explained above and illustrated in FIG. 3A, the metal fillers 308 are randomly distributed though out the magnetic mold compound 306 in a uniform manner. On the other hand, in FIG. 3B the lower mold chase 302 has been exposed to a magnetic field and thus a portion 312 of the lower mold chase 302 has become magnetized. As a result, the metal fillers 308 are attracted to the magnetized portion 312 of the lower mold chase 302 and thus become concentrated near the magnetized portion 312. Consequently, the metal fillers 308 are not randomly distributed throughout the magnetic mold compound 306 thereby compromising the molding process and the performance of the IC.

This phenomenon is also illustrated in FIG. 6A. The electronic device 600A illustrated in FIG. 6A was molded with the mold compound 608 where the mold chase was not magnetized. As a result, the metal fillers 618 are randomly distributed throughout the mold compound 608. On the other hand, the electronic device 600B illustrated in FIG. 6B was molded with the mold compound 608 where the mold chase was magnetized during the molding process. As a result, the pattern of the metal fillers 618 in the mold compound 608 is not random. Rather, the metal fillers 618 are concentrated in a pattern due to the mold chase being influenced by a magnetic field. Therefore, a distinction can be made between electronic devices molded with a mold compound (e.g., magnetic mold compound) with metal fillers where the mold chase was not magnetized (FIG. 6A) and was magnetized (FIG. 6B).

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. A method comprising:
performing a molding process with a mold machine to form a magnetic mold compound on electronic devices;
detecting magnetic fields in a mold chase of the mold machine via a gaussmeter;
ceasing the molding process of the mold machine responsive to determining that a strength of at least one detected magnetic field exceeds a threshold; and
demagnetizing the mold chase via a demagnetizer.

2. The method of claim 1, wherein performing a molding process with a mold machine to form a magnetic mold compound on electronic devices includes:
dispensing the magnetic mold compound in a powder state into a cavity of a lower mold chase of the mold chase;
heating the lower mold chase to a temperature to transform the magnetic mold compound from the powder state to a liquid state;
clamping the lower mold chase to an upper mold chase under a pressure for a time period to form the magnetic mold compound on the electronic devices attached to the upper mold chase;
unclamping the lower mold chase and the upper mold chase; and
removing the electronic devices from the mold chase.

3. The method of claim 1, wherein the gaussmeter is integrated into the mold machine, and wherein detecting magnetic fields in the mold chase of the mold machine via a gaussmeter includes coupling probes from the integrated gaussmeter to the mold chase.

4. The method of claim 1, wherein the gaussmeter is external to the mold machine, and wherein detecting magnetic fields in a mold chase of the mold machine via a gaussmeter includes coupling probes from the external gaussmeter to the mold chase.

5. The method of claim 1, wherein ceasing the molding process of the mold machine responsive to determining that a strength of at least one detected magnetic field exceeds a threshold includes comparing the determined magnetic field strength measured by the gaussmeter to the threshold stored in a memory of a controller of the mold machine.

6. The method of claim 1, wherein the demagnetizer is external to the mold machine, and wherein demagnetizing the mold chase via the demagnetizer includes:
removing a lower mold chase of the mold chase from the mold machine;
manually demagnetizing the lower mold chase via the external demagnetizer; and
re-installing the lower mold chase in the mold machine.

7. The method of claim 1, wherein the demagnetizer is integrated into the mold machine, and wherein demagnetizing the mold chase via the demagnetizer includes automatically demagnetizing a lower mold chase of the mold chase via the integrated demagnetizer proximate to the lower mold chase.

8. A method of demagnetizing a mold machine during molding a mold compound on electronic devices, the method comprising:
activating a gaussmeter coupled to a mold chase in the mold machine to detect magnetic fields;
demagnetizing the mold chase via a demagnetizer responsive to detecting that a strength of at least one detected magnetic field exceeds a threshold;
dispensing a magnetic mold compound in a powder state into a cavity of a lower mold chase;
heating the lower mold chase to a temperature to transform the magnetic mold compound from the powder state to a liquid state;
clamping the lower mold chase to an upper mold chase for a time period to form the magnetic mold compound on the electronic devices attached to the upper mold chase;
unclamping the lower mold chase and the upper mold chase; and
removing the electronic devices from the upper mold chase.

9. The method of claim 8, wherein the gaussmeter is integrated into the mold machine, and wherein activating a gaussmeter coupled to a mold chase in the mold machine to detect magnetic fields further includes coupling probes from the integrated gaussmeter to the mold chase.

10. The method of claim 8, wherein the gaussmeter is external to the mold machine, and wherein activating a gaussmeter coupled to a mold chase in the mold machine to detect magnetic fields further includes coupling probes from the external gaussmeter to the mold chase.

11. The method of claim 8, wherein prior to demagnetizing the mold chase via a demagnetizer responsive to detecting that a strength of at least one detected magnetic field exceeds a threshold, the method comprising determining if the strength of the detected magnetic field exceeds the threshold by comparing the determined strength of the magnetic field measured by the gaussmeter to the threshold stored in a memory of a controller of the mold machine.

12. The method of claim 11 further comprising ceasing operation of the mold machine if the strength of the detected magnetic field exceeds the threshold.

13. The method of claim 12, wherein the demagnetizer is external to the mold machine, and wherein demagnetizing the mold chase via a demagnetizer responsive to detecting that a strength of at least one detected magnetic field exceeds a threshold includes:
removing the lower mold chase from the mold machine;
manually demagnetizing the lower mold chase via the external demagnetizer; and
re-installing the lower mold chase in the mold machine.

14. The method of claim 12, wherein the demagnetizer is integrated into the mold machine, and wherein demagnetizing the mold chase via a demagnetizer responsive to detecting that a strength of at least one detected magnetic field exceeds a threshold includes automatically demagnetizing the mold chase via the integrated demagnetizer proximate to the lower mold chase.

15. A mold system comprising:
a mold machine configured to form a mold compound on electronic devices, the mold machine including a controller and a mold chase;
a gaussmeter coupled to the mold machine configured to detect magnetic fields of the mold chase;
a controller configured to provide a control signal responsive to determining a strength of at least one of the detected magnetic fields exceeds a magnetization threshold; and
a demagnetizer configured to demagnetize the mold chase responsive to the control signal.

16. The mold system of claim 15, wherein the mold compound is a magnetic mold compound, wherein the mold chase includes a lower chase and an upper chase, and wherein the lower chase includes a cavity defined therein to receive the magnetic mold compound.

17. The mold chase of claim 16, wherein the gaussmeter is integrated into the mold machine and coupled to the lower chase via one or more probes.

18. The mold chase of claim 16, wherein the gaussmeter is external to the mold machine and is coupled to the lower chase via one or more probes.

19. The mold chase of claim 16, wherein the demagnetizer is integrated into the mold machine and located proximate to the lower chase.

20. The mold chase of claim 16, wherein the demagnetizer is external to the mold machine.

21. An electronic device comprising:
a leadframe having a die pad and leads;
a die disposed on the die pad, the die having an active side;
wire bonds attached to the active side of the die and to the leads; and
a mold compound encapsulating the die and the wire bonds,
wherein metal fillers in the mold compound are randomly dispersed.

22. The electronic device of claim 21, wherein a patterning of the metal fillers is not reflective of being influenced by a magnetic field.

23. The electronic device of claim 21, wherein the mold compound is a magnetic mold compound.
